(19) United States
(12) Patent Application Publication
(10) Pub. No.: US 2026/0277108 A1
(43) Pub. Date: Sep. 17, 2026

(54) LASER APPARATUS, LASER APPARATUS WAVELENGTH CONTROL METHOD, AND ELECTRONIC DEVICE MANUFACTURING METHOD

(71) Applicant: Gigaphoton Inc., Tochigi (JP)

(72) Inventor: Takayuki OSANAI, Tochigi (JP)

(73) Assignee: Gigaphoton Inc., Tochigi (JP)

(21) Appl. No.: 19/558,898

(22) Filed: Mar. 6, 2026

Related U.S. Application Data
(63) Continuation of application No. PCT/JP2023/036543, filed on Oct. 6, 2023.

(51) Int. Cl. G03F 7/00; G02F 1/35; G02F 1/355; H01S 3/00; H01S 3/094; H01S 3/0941; H01S 3/10; H01S 3/23

(52) U.S. Cl. CPC G03F 7/70025; G02F 1/3534; G02F 1/3551; G03F 7/70041; H01S 3/0085; H01S 3/0092; H01S 3/094076; H01S 3/0941; H01S 3/10023; H01S 3/10092; H01S 3/2308

(57) ABSTRACT

A laser apparatus includes a first semiconductor laser that outputs a continuously oscillating first seed laser beam having a first wavelength, a second semiconductor laser that outputs a continuously oscillating second seed laser beam having a second wavelength different from the first wavelength, an optical switch that outputs selected one of the first seed laser beam and the second seed laser beam as a selected seed laser beam, a first solid-state amplifier that pulses and amplifies the selected seed laser beam to output a first pulse laser beam, a wavelength conversion system that outputs a second pulse laser beam by wavelength conversion using the first pulse laser beam, an excimer amplifier that amplifies the second pulse laser beam to output a third pulse laser beam, a beam characteristic measuring instrument that measures a wavelength of the third pulse laser beam, and a processor that selects one of the first seed laser beam and the second seed laser beam as the selected seed laser beam based on a target wavelength, and controls a wavelength of the first semiconductor laser or the second semiconductor laser that outputs the selected seed laser beam based on the wavelength measured by the beam characteristic measuring instrument such that the wavelength of the third pulse laser beam becomes the target wavelength.

### CROSS-REFERENCE TO RELATED APPLICATIONS

The present application is a continuation application of International Application No. PCT/JP2023/036543, filed on Oct. 6, 2023, the entire contents of which are hereby incorporated by reference.

### BACKGROUND

### 1. Technical Field

The present disclosure relates to a laser apparatus, a laser apparatus wavelength control method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: International Patent Publication No. 2023/013025
Patent Document 2: International Patent Publication No. 2022/249444

### SUMMARY

A laser apparatus according to one aspect of the present disclosure includes a first semiconductor laser, a second semiconductor laser, an optical switch, a first solid-state amplifier, a wavelength conversion system, an excimer amplifier, a beam characteristic measuring instrument, and a processor. The first semiconductor laser is configured to output a continuously oscillating first seed laser beam having a first wavelength. The second semiconductor laser is configured to output a continuously oscillating second seed laser beam having a second wavelength different from the first wavelength. The optical switch is configured to output selected one of the first seed laser beam and the second seed laser beam as a selected seed laser beam. The first solid-state amplifier is configured to pulse and amplify the selected seed laser beam and to output a first pulse laser beam. The wavelength conversion system is configured to output a second pulse laser beam by wavelength conversion using the first pulse laser beam. The excimer amplifier is configured to amplify the second pulse laser beam and to output a third pulse laser beam. The beam characteristic measuring instrument is configured to measure a wavelength of the third pulse laser beam. The processor is configured to select one of the first seed laser beam and the second seed laser beam as the selected seed laser beam based on a target wavelength, and to control a wavelength of the first semiconductor laser or the second semiconductor laser that outputs the selected seed laser beam based on the wavelength measured by the beam characteristic measuring instrument such that the wavelength of the third pulse laser beam becomes the target wavelength.

A laser apparatus wavelength control method according to one aspect of the present disclosure includes outputting a continuously oscillating first seed laser beam having a first wavelength by a first semiconductor laser, outputting a continuously oscillating second seed laser beam having a second wavelength different from the first wavelength by a second semiconductor laser, outputting selected one of the first seed laser beam and the second seed laser beam as a selected seed laser beam from an optical switch, pulsing and amplifying the selected seed laser beam and outputting a first pulse laser beam by a first solid-state amplifier, outputting a second pulse laser beam by wavelength conversion using the first pulse laser beam by a wavelength conversion system, amplifying the second pulse laser beam and outputting a third pulse laser beam by an excimer amplifier, measuring a wavelength of the third pulse laser beam by a beam characteristic measuring instrument, and selecting one of the first seed laser beam and the second seed laser beam as the selected seed laser beam based on a target wavelength and controlling a wavelength of the first semiconductor laser or the second semiconductor laser that outputs the selected seed laser beam based on the wavelength measured by the beam characteristic measuring instrument such that the wavelength of the third pulse laser beam becomes the target wavelength.

An electronic device manufacturing method according to one aspect of the present disclosure includes generating a laser beam with a laser apparatus, outputting the laser beam to an exposure apparatus, and exposing a photosensitive substrate to the laser beam in the exposure apparatus to manufacture an electronic device. The laser apparatus includes a first semiconductor laser configured to output a continuously oscillating first seed laser beam having a first wavelength, a second semiconductor laser configured to output a continuously oscillating second seed laser beam having a second wavelength different from the first wavelength, an optical switch configured to output selected one of the first seed laser beam and the second seed laser beam as a selected seed laser beam, a first solid-state amplifier configured to pulse and amplify the selected seed laser beam and to output a first pulse laser beam, a wavelength conversion system configured to output a second pulse laser beam by wavelength conversion using the first pulse laser beam, an excimer amplifier configured to amplify the second pulse laser beam and to output a third pulse laser beam, a beam characteristic measuring instrument configured to measure a wavelength of the third pulse laser beam, and a processor configured to select one of the first seed laser beam and the second seed laser beam as the selected seed laser beam based on a target wavelength, and to control a wavelength of the first semiconductor laser or the second semiconductor laser that outputs the selected seed laser beam based on the wavelength measured by the beam characteristic measuring instrument such that the wavelength of the third pulse laser beam becomes the target wavelength.

### BRIEF DESCRIPTION OF THE DRAWINGS

Some embodiments of the present disclosure will be described below, by way of example only, with reference to the accompanying drawings.

FIG. 1 is a graph for explaining a two-wavelength parameter in two-wavelength exposure.

FIG. 2 is a diagram schematically illustrating a configuration of an exposure system.

FIG. 3 is a top view illustrating a configuration of a laser apparatus of a comparative example.

FIG. 4 is a side view illustrating the configuration of the laser apparatus of the comparative example.

FIG. 5 is a diagram schematically illustrating a configuration of a laser apparatus according to Embodiment 1.

FIG. 6 is an explanatory diagram illustrating an example of changing a wavelength for each pulse by an optical switch.

FIG. 7 is an explanatory diagram illustrating an example of changing the wavelength for every four pulses by the optical switch.

FIG. 8 is a flowchart illustrating Example 1 of a processing procedure of a laser control processor in Embodiment 1.

FIG. 9 is a flowchart illustrating Example 2 of the processing procedure of the laser control processor in Embodiment 1.

FIG. 10 is a diagram schematically illustrating a configuration of a distributed feedback semiconductor laser.

FIG. 11 is a diagram schematically illustrating a configuration of a wavelength conversion system.

FIG. 12 is a graph illustrating wavelength conversion efficiency curves of a KBBF crystal and an LBO crystal, respectively.

FIG. 13 is a flowchart illustrating an example of controlling an incident angle of a nonlinear crystal, executed by the laser control processor.

FIG. 14 is a graph illustrating a relation between a wavelength after excimer amplification and wavelength conversion efficiency.

FIG. 15 is a graph illustrating the relation between the wavelength after excimer amplification and the wavelength conversion efficiency.

FIG. 16 is a graph illustrating an example of a case of performing control to an incident angle corresponding to a target center wavelength after wavelength conversion based on a relation between the wavelength after the wavelength conversion of the KBBF crystal and the incident angle at which the wavelength conversion efficiency is maximized.

FIG. 17 is a graph illustrating an example of a case of performing control to an incident angle corresponding to a target short wavelength after wavelength conversion based on the relation between the wavelength after the wavelength conversion of the KBBF crystal and the incident angle at which the wavelength conversion efficiency is maximized.

FIG. 18 is a graph illustrating an example of a case of performing control to an incident angle corresponding to a target long wavelength after wavelength conversion based on the relation between the wavelength after the wavelength conversion of the KBBF crystal and the incident angle at which the wavelength conversion efficiency is maximized.

FIG. 19 is a diagram schematically illustrating a configuration of a solid-state seeder applied to a laser apparatus according to Embodiment 2.

FIG. 20 is a graph illustrating an example of a case of performing control to an incident angle corresponding to a target center wavelength after wavelength conversion based on a relation between the wavelength after the wavelength conversion of a second CLBO crystal and the incident angle at which the wavelength conversion efficiency is maximized.

FIG. 21 is a graph illustrating an example of a case of performing control to an incident angle corresponding to a target short wavelength after wavelength conversion based on the relation between the wavelength after the wavelength conversion of the second CLBO crystal and the incident angle at which the wavelength conversion efficiency is maximized.

FIG. 22 is a graph illustrating an example of a case of performing control to an incident angle corresponding to a target long wavelength after wavelength conversion based on the relation between the wavelength after the wavelength conversion of the second CLBO crystal and the incident angle at which the wavelength conversion efficiency is maximized.

FIG. 23 is a diagram schematically illustrating a configuration of an exposure apparatus.

### DESCRIPTION OF EMBODIMENTS

### <Contents>

1. Terms
2. Comparative Example
   2.1 Exposure System
      2.1.1 Configuration
      2.1.2 Operation
   2.2 Laser Apparatus
      2.2.1 Configuration
      2.2.2 Operation
3. Problem
4. Embodiment 1
   4.1 Laser Apparatus
      4.1.1 Configuration
      4.1.2 Operation
         4.1.2.1 Example 1 of Wavelength Control Method
         4.1.2.2 Example 2 of Wavelength Control Method
   4.2 Example of Semiconductor Laser
      4.2.1 Configuration
      4.2.2 Operation
   4.3 Example of Wavelength Conversion System
      4.3.1 Configuration
      4.3.2 Operation
      4.3.3 Method for Controlling Incident Angle of Nonlinear Crystal
         4.3.3.1 Flowchart Example
         4.3.3.2 Operation
   4.4 Effect
5. Embodiment 2
   5.1 Configuration
   5.2 Operation
   5.3 Effect
6. Electronic Device Manufacturing Method
7. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Terms

In the present specification, “two-wavelength exposure” refers to performing exposure in such a way that an integrated exposure spectrum has two peaks by switching a wavelength to λ_{S} and λ_{L} for each pulse or every few pulses to cause laser oscillation.

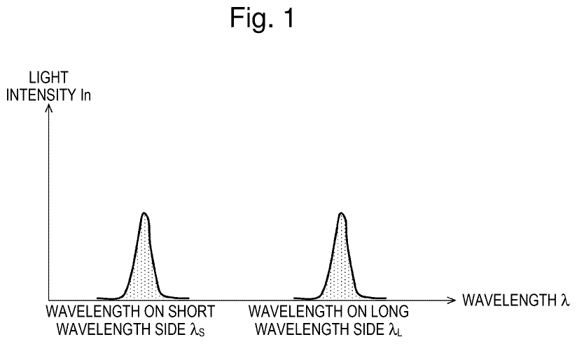

FIG. 1 is a graph for explaining a two-wavelength parameter in the two-wavelength exposure. In FIG. 1, a horizontal axis represents a wavelength λ, and a vertical axis represents light intensity In. As illustrated in FIG. 1, a wavelength on a short wavelength side in the two-wavelength exposure is λ_{S}, and a wavelength on a long wavelength side is λ_{L}. A center wavelength λc of a two-wavelength spectrum is expressed as (λ_{L}+λ_{S})/2.

### 2. Comparative Example

### 2.1 Exposure System

### 2.1.1 Configuration

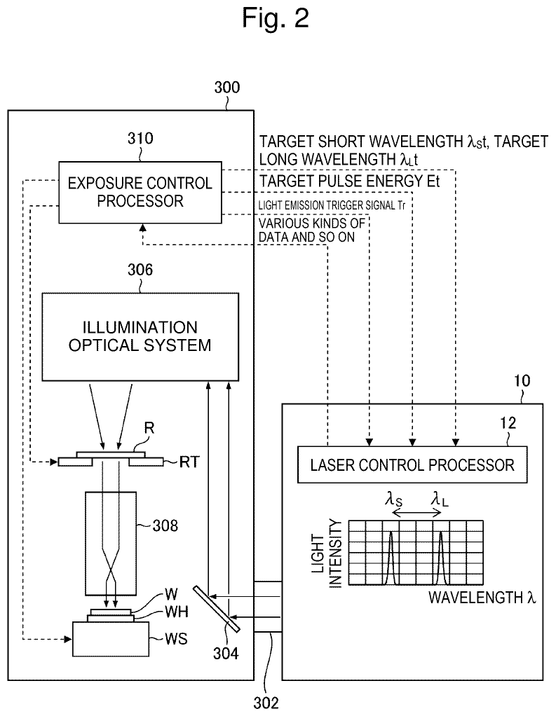

FIG. 2 is a diagram schematically illustrating a configuration of an exposure system. The exposure system includes a laser apparatus 10, an exposure apparatus 300, and a beam delivery unit (BDU) 302. The laser apparatus 10 includes a laser control processor 12. In the present specification, a processor is a processing device including a storage device in which a control program is stored, and a CPU (Central Processing Unit) which executes the control program. The processor is specially configured or programmed to execute various kinds of processing included in the present disclosure.

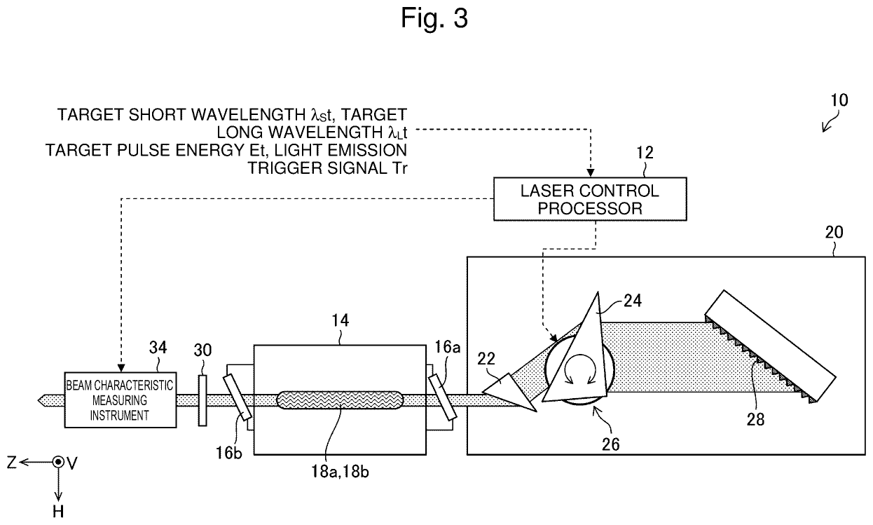

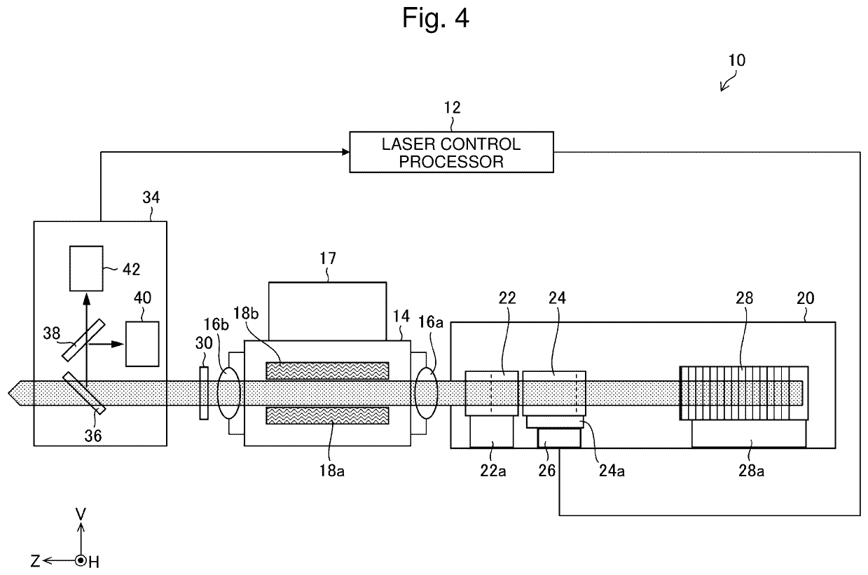

The laser apparatus 10 is configured to output a pulse laser beam capable of changing an oscillation wavelength toward the exposure apparatus 300. A configuration of the laser apparatus 10 will be described later (FIGS. 3 and 4).

The exposure apparatus 300 includes a high reflective mirror 304, an illumination optical system 306, a reticle stage RT, a projection optical system 308, a wafer stage WS, and an exposure control processor 310. The wafer stage WS is provided with a wafer holder WH, and a wafer W is placed on the wafer holder WH.

The BDU 302 is an optical system that transmits the pulse laser beam from the laser apparatus 10 to the exposure apparatus 300. The high reflective mirror 304 is disposed such that the pulse laser beam that has passed through the BDU 302 enters the illumination optical system 306.

The illumination optical system 306 is an optical system that shapes a beam of the pulse laser beam incident from the laser apparatus 10 and guides it to a reticle R placed on the reticle stage RT. The illumination optical system 306 shapes the beam so as to have a beam shape with a generally rectangular beam cross section of the pulse laser beam and a roughly uniform light intensity distribution, and illuminates a reticle pattern of the reticle R. The projection optical system 308 images the pulse laser beam having transmitted through the reticle R on the wafer W on the wafer holder WH by reduced projection. The wafer W is a photosensitive substrate such as a semiconductor wafer on which a resist film is applied.

The exposure control processor 310 is a processing device including a storage device in which a control program is stored, and a CPU which executes the control program. The exposure control processor 310 generally controls the exposure apparatus 300. The exposure control processor 310 is connected to the reticle stage RT and the wafer stage WS. In addition, the exposure control processor 310 is connected to the laser control processor 12.

### 2.1.2 Operation

It is known that processing with multi-wavelength (for example, two-wavelength) pulses having peak intensity at a plurality of center wavelengths during exposure of resist results in a deep focal depth and improved processing accuracy.

The exposure control processor 310 transmits various kinds of parameters including a target short wavelength λ_{S}t, a target long wavelength λ_{L}t, and target pulse energy Et, and a light emission trigger signal Tr to the laser control processor 12. The laser control processor 12 controls the laser apparatus 10 according to these parameters and signal. That is, the laser control processor 12 controls the oscillation wavelength by periodically changing a target wavelength so that a wavelength λ of the pulse laser beam output from the laser apparatus 10 becomes the target short wavelength λ_{S}t or the target long wavelength λ_{L}t, also controls excitation intensity so that pulse energy E becomes the target pulse energy Et, and outputs the pulse laser beam in accordance with the light emission trigger signal Tr.

In this way, the laser apparatus 10 outputs the two-wavelength pulse laser beam controlled to be the target wavelength towards the exposure apparatus 300 in accordance with the light emission trigger signal Tr.

The exposure control processor 310 translates the reticle stage RT and the wafer holder WH on the wafer stage WS in directions opposite to each other in synchronization.

Accordingly, the wafer W is exposed to the pulse laser beam reflecting the reticle pattern.

### 2.2 Laser Apparatus

### 2.2.1 Configuration

FIGS. 3 and 4 are a top view and a side view illustrating the configuration of the laser apparatus 10 according to the comparative example. The comparative example of the present disclosure is an example recognized by the applicant as known only by the applicant, and is not a publicly known example admitted by the applicant.

The laser apparatus 10 illustrated in FIGS. 3 and 4 is a wavelength-variable line narrowing excimer laser apparatus, and includes a chamber 14, a power source 17, a line narrowing module (LNM) 20, an output coupling mirror 30, a beam characteristic measuring instrument 34, and the laser control processor 12.

The output coupling mirror 30 and the LNM 20 together form an optical resonator, and the chamber 14 is disposed on an optical path of the optical resonator.

The LNM 20 includes multiple (for example, two) prisms 22 and 24, a rotation stage 26, and a grating 28. The prisms 22 and 24 and the grating 28 are supported by holders 22a, 24a, and 28a, respectively.

The prisms 22 and 24 are disposed to function as beam expanders. The grating 28 is disposed in Littrow arrangement such that an incident angle matches a diffracting angle.

The prism 24 is disposed on the rotation stage 26 which rotates around an axis parallel to a V axis, and is disposed so that the incident angle to the grating 28 changes as the prism 24 rotates.

The chamber 14 includes windows 16a and 16b and a pair of electrodes 18a and 18b. The chamber 14 is filled with laser gas that includes Ar gas or Kr gas as rare gas, F2 gas as halogen gas, and Ne gas as buffer gas.

The power source 17 is a pulse power module (PPM) and includes a switch and a charging capacitor that are not illustrated. The laser apparatus 10 includes a non-illustrated charger, and the charger charges the charging capacitor of the power source 17 according to commands from the laser control processor 12. When the switch is turned ON, the power source 17 is connected so that a high voltage is applied between the electrodes 18a and 18b.

The electrodes 18a and 18b face each other in a V direction within the chamber 14, and are disposed such that a longitudinal direction of the electrodes 18a and 18b matches a direction of the optical path of the optical resonator.

The windows 16a and 16b are disposed such that the pulse laser beam amplified by discharge excitation between the electrodes 18a and 18b passes through.

The output coupling mirror 30 is coated with a film that reflects a part of the pulse laser beam and transmits the other part.

The beam characteristic measuring instrument 34 includes a first beam splitter 36, a second beam splitter 38, a spectrum detector 40, and an energy detector 42.

The first beam splitter 36 is disposed such that, on an optical path of the pulse laser beam output from the output coupling mirror 30, the pulse laser beam reflected by the first beam splitter 36 enters the second beam splitter 38.

The second beam splitter 38 is disposed such that the pulse laser beam reflected by the second beam splitter 38 enters the spectrum detector 40 and the pulse laser beam transmitted through the second beam splitter 38 enters the energy detector 42.

The spectrum detector 40 monitors a spectrum of the incident pulse laser beam, and detects a wavelength of the incident pulse laser beam. The spectrum detector 40 may be, for example, an etalon spectrometer. The etalon spectrometer includes a diffusion plate that diffuses sample light, an etalon, a light condensing lens disposed on an exit side of the etalon, and a photodiode array disposed on a focal plane of the light condensing lens for detecting a pattern of interference fringes, and can detect the wavelength by measuring a diameter of the interference fringes.

The energy detector 42 includes a non-illustrated photosensor. The photosensor may be a photodiode that is resistant to ultraviolet light and is excellent in high-speed responsiveness. The photosensor detects pulse energy of the incident pulse laser beam.

Note that the laser apparatus 10 is provided with a non-illustrated exit shutter in a rear stage of the beam characteristic measuring instrument 34. The exit shutter is disposed on an optical path of the pulse laser beam to be output from the laser apparatus 10 to outside, and is configured to output the pulse laser beam to outside and to shield the pulse laser beam. The pulse laser beam transmitted through the first beam splitter 36 is output from the laser apparatus 10 via the exit shutter.

### 2.2.2 Operation

The laser control processor 12 reads data of the target short wavelength λ_{S}t, the target long wavelength λ_{L}t, and the target pulse energy Et for each wavelength from the exposure apparatus 300. The laser control processor 12 also receives the light emission trigger signal Tr.

Based on the light emission trigger signal Tr received from the exposure apparatus 300, the laser control processor 12 turns ON the switch of the power source 17.

When the switch of the power source 17 is turned ON, the high voltage is applied between the electrode 18a and the electrode 18b. Then, when discharge occurs between the electrodes 18a and 18b, the laser gas is excited.

When the laser gas is excited, a line-narrowed pulse laser beam is output from the output coupling mirror 30 by the optical resonator. The wavelength of the pulse laser beam is, for example, an ultraviolet wavelength of 150 nm to 380 nm.

The energy detector 42 detects the pulse energy of the pulse laser beam output from the output coupling mirror 30. The laser control processor 12 calculates the pulse energy E based on a detection result received from the energy detector 42. The laser control processor 12 controls a voltage of a high voltage pulse applied between the electrode 18a and the electrode 18b such that the pulse energy E based on the detection result of the energy detector 42 becomes the target pulse energy Et.

The spectrum detector 40 detects a spectral linewidth and a wavelength of the pulse laser beam output from the output coupling mirror 30. The spectrum detector 40 detects the wavelength λ of the pulse laser beam for each pulse. The laser control processor 12 calculates the wavelength λ based on a wavelength detection result received from the spectrum detector 40. Then, the rotation stage 26 of the prism 24 is controlled such that the wavelength λ of the pulse laser beam output from the laser apparatus 10 becomes the target short wavelength λ_{S}t or the target long wavelength λ_{L}t.

### 3. Problem

In the laser apparatus 10 according to the comparative example, a speed of wavelength change during the two-wavelength exposure depends on a rotation speed of the rotation stage 26. In addition, the time required for the wavelength change is the inverse of the oscillation frequency. In a case of the configuration of the laser apparatus 10, for example, the wavelength can be changed within the time of 250 μs (equivalent to 4 kHz), but the wavelength cannot be changed in 167 μs (equivalent to 6 kHz). Therefore, it is difficult to stabilize the wavelength of the pulse laser beam output from the laser apparatus 10 to the target two wavelengths (λ_{S}t, λ_{L}t), respectively. Even at a repetition frequency of 4 kHz or higher, it is desirable to stabilize the wavelength of the pulse laser beam to be output to the target two wavelengths, respectively.

### 4. Embodiment 1

### 4.1 Laser Apparatus

### 4.1.1 Configuration

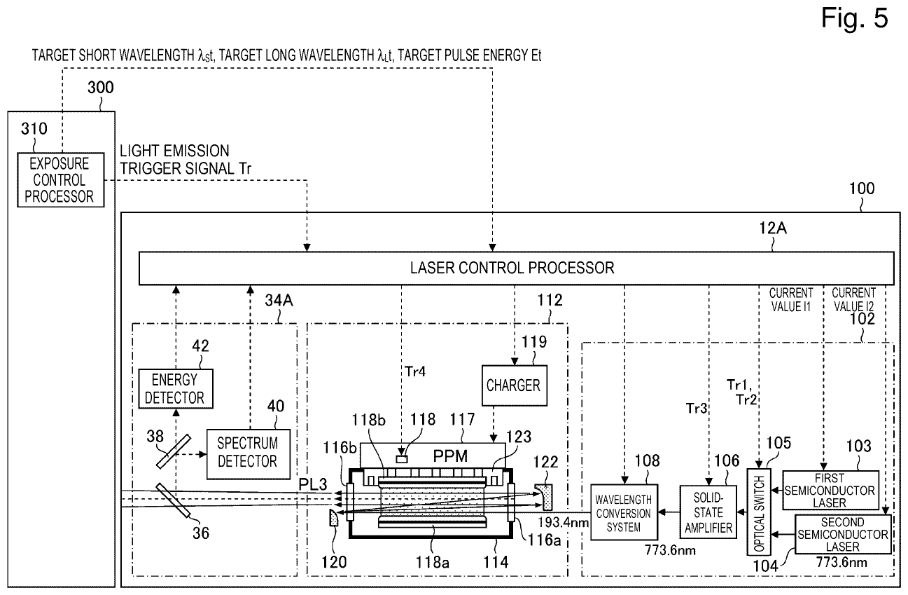

FIG. 5 is a diagram schematically illustrating a configuration of a laser apparatus 100 according to Embodiment 1. The laser apparatus 100 includes a solid-state seeder 102 as a master oscillator (MO), an excimer amplifier 112 as a power amplifier (PA), a beam characteristic measuring instrument 34A, and a laser control processor 12A.

The solid-state seeder 102 includes a first semiconductor laser 103, a second semiconductor laser 104, an optical switch 105, a solid-state amplifier 106, and a wavelength conversion system 108.

Each of the first semiconductor laser 103 and the second semiconductor laser 104 continuously oscillates in a single longitudinal mode around a wavelength of 773.6 nm, and both have slightly different wavelengths. Each of the first semiconductor laser 103 and the second semiconductor laser 104 may be a continuously oscillating distributed feedback semiconductor laser. The wavelengths of the first semiconductor laser 103 and the second semiconductor laser 104 are within a range of 700 nm to 800 nm respectively, and a wavelength difference between the two may be within a range of 1 pm to 110 pm.

The optical switch 105 selects one of laser beams output from the first semiconductor laser 103 and the second semiconductor laser 104 and transmits it to a subsequent stage. The laser beam to be transmitted to the subsequent stage can be switched, for example, at a cycle of 10 kHz.

The optical switch 105 selects the laser beam and transmits it to the subsequent stage according to a first seed trigger signal Tr1 or a second seed trigger signal Tr2 received from the laser control processor 12A. The optical switch 105 may use mechanical optical path switching, an electro-optic effect switch, a thermo-optic optical switch, a semiconductor waveguide optical switch, or the like. Note that means for the mechanical optical path switching may include MEMS (Micro Electro Mechanical Systems).

The solid-state amplifier 106 pulses the laser beam selected by the optical switch 105 and amplifies the energy of the laser beam. The solid-state amplifier 106 includes a titanium sapphire crystal and a pumping pulse laser. The solid-state amplifier 106 is an example of a “first solid-state amplifier” in the present disclosure.

The wavelength conversion system 108 includes a nonlinear crystal that converts a first pulse laser beam having a near-infrared wavelength output from the solid-state amplifier 106 to a second pulse laser beam having an ultraviolet wavelength. The nonlinear crystal may be a combination of an LBO crystal and a KBBF crystal. “LBO” is represented by a chemical formula of LiB₃O₅. “KBBF” is represented by a chemical formula of KBe₂BO₃F₂.

Note that optical fibers may be used to transmit the laser beam from the first semiconductor laser 103 or the second semiconductor laser 104 to the optical switch 105 and to transmit the laser beam from the optical switch 105 to the solid-state amplifier 106.

The excimer amplifier 112 includes a chamber 114, a PPM 117, a charger 119, a convex mirror 120, and a concave mirror 122. The chamber 114 includes windows 116a and 116b, a pair of electrodes 118a and 118b, and an electric insulating member 123. The chamber 114 is filled with ArF laser gas.

The PPM 117 includes a switch 118 and a non-illustrated charging capacitor. The PPM 117 is connected with the electrode 118b via a feedthrough in the electric insulating member 123.

The charger 119 is connected to the non-illustrated charging capacitor. The electrode 118a is connected to a ground potential.

The convex mirror 120 and the concave mirror 122 are disposed such that the second pulse laser beam output from the wavelength conversion system 108 passes through a discharge space between the electrodes 118a and 118b three times so as to expand the beam.

The beam characteristic measuring instrument 34A may be configured similarly to the beam characteristic measuring instrument 34 described in FIG. 4. The first beam splitter 36, the second beam splitter 38, and the energy detector 42 are disposed such that a part of a third pulse laser beam PL3 output from the excimer amplifier 112 is reflected by the first beam splitter 36, is transmitted through the second beam splitter 38 further, and enters the energy detector 42. In addition, the spectrum detector 40 is disposed such that the third pulse laser beam PL3 reflected by the second beam splitter 38 enters the spectrum detector 40.

### 4.1.2 Operation

The first semiconductor laser 103 continuously oscillates a first seed laser beam having a first wavelength at all times.

The second semiconductor laser 104 continuously oscillates a second seed laser beam having a second wavelength at all times.

The laser control processor 12A determines the seed laser beam to be transmitted to the subsequent stage by the optical switch 105 for each pulse. Then, according to this determination, the laser control processor 12A transmits the first seed trigger signal Tr1 or the second seed trigger signal Tr2 to the optical switch 105. For example, when the first seed trigger signal Tr1 is ON, the first seed laser beam output from the first semiconductor laser 103 is transmitted to the subsequent stage of the optical switch 105. Also, when the second seed trigger signal Tr2 is ON, the second seed laser beam output from the second semiconductor laser 104 is transmitted to the subsequent stage of the optical switch 105. The selected seed laser beam selected by the optical switch 105 enters the solid-state amplifier 106.

The solid-state amplifier 106 pulses and amplifies the selected seed laser beam selected by the optical switch 105 and outputs the first pulse laser beam. When an MO trigger signal Tr3 is received from the laser control processor 12A, the solid-state amplifier 106 outputs a pulse laser beam from the pumping pulse laser. While the pulse laser beam from the pumping pulse laser is incident on the titanium sapphire crystal, the selected seed laser beam incident on the titanium sapphire crystal is amplified. A pulse width of the pulse laser beam output from the pumping pulse laser is, for example, 10 to 40 ns.

The first pulse laser beam pulsed and amplified in the solid-state amplifier 106 is converted to a desired ultraviolet wavelength in the wavelength conversion system 108. For example, using the first seed laser beam having the first wavelength of 773.600 nm output from the first semiconductor laser 103, a fourth harmonic is generated in the wavelength conversion system 108, and is converted to the second pulse laser beam having the wavelength of 193.400 nm.

In addition, using the second seed laser beam having the second wavelength of 773.604 nm output from the second semiconductor laser 104, the fourth harmonic is generated in the wavelength conversion system 108, and is converted to the second pulse laser beam having the wavelength of 193.401 nm.

Thus, it is possible to change the wavelength around 193 nm of the first pulse laser beam output from the wavelength conversion system 108 by the wavelength difference of 1 pm. It is preferable to select the first wavelength output from the first semiconductor laser 103 and the second wavelength such that the wavelength difference of the pulse laser beam output from the wavelength conversion system 108 is within 1 pm.

The laser control processor 12A transmits a PA trigger signal Tr4 to the switch 118 of the PPM 117 such that discharge occurs between the electrodes in synchronization with entry of the second pulse laser beam output from the solid-state seeder 102 to the discharge space between the electrodes 118a and 118b in the chamber 114 of the excimer amplifier 112.

As a result, the second pulse laser beam output from the solid-state seeder 102 is amplified by the excimer amplifier 112 through three-time passing.

The laser control processor 12A can change the wavelength of the third pulse laser beam PL3 output from the excimer amplifier 112 by switching the laser beam to be transmitted to the subsequent stage by the optical switch 105.

The energy detector 42 detects the pulse energy of the third pulse laser beam PL3 output from the excimer amplifier 112.

The laser control processor 12A calculates the pulse energy E based on the detection result received from the energy detector 42. Then, the laser control processor 12A controls the voltage of the high voltage pulse applied between the electrode 118a and the electrode 118b such that the pulse energy E of the third pulse laser beam PL3 output from the laser apparatus 100 becomes the target pulse energy Et.

The spectrum detector 40 detects a spectral linewidth and a wavelength of the third pulse laser beam PL3 output from the excimer amplifier 112.

The laser control processor 12A calculates the wavelength λ based on the wavelength detection result received from the spectrum detector 40. Then, the laser control processor 12A controls at least one of a current value of a current flowing through a semiconductor of the distributed feedback semiconductor laser and a temperature of the semiconductor such that the wavelength 2 of the third pulse laser beam PL3 output from the laser apparatus 100 becomes the target wavelength. The laser control processor 12A is an example of a “processor” in the present disclosure.

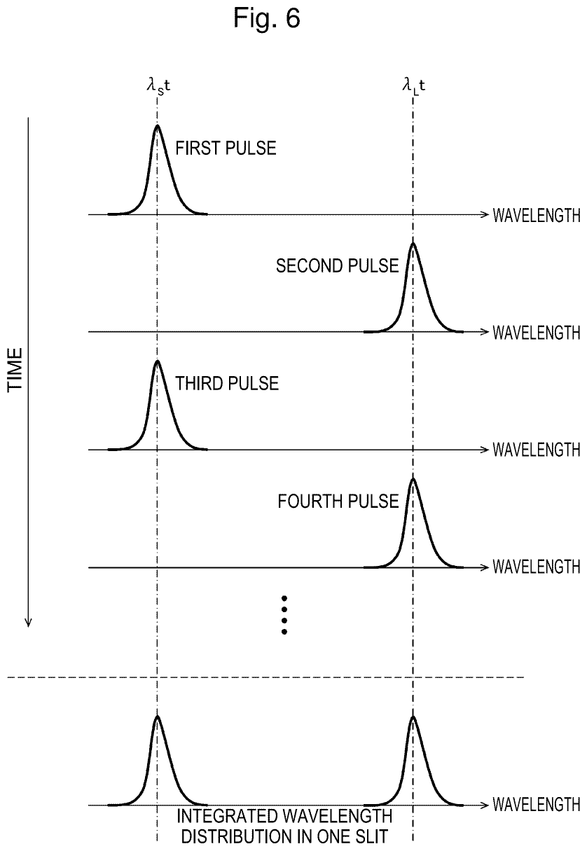

FIG. 6 is an explanatory diagram illustrating an example of changing the wavelength for each pulse by the optical switch 105. For the wavelength change using the optical switch 105, as illustrated in FIG. 6, the target short wavelength λ_{S}t and the target long wavelength λ_{L}t may be alternately oscillated by changing the wavelength for each pulse. A bottom row of FIG. 6 illustrates an integrated wavelength distribution in one slit when step-and-scan exposure is performed by alternately switching two wavelengths for each pulse.

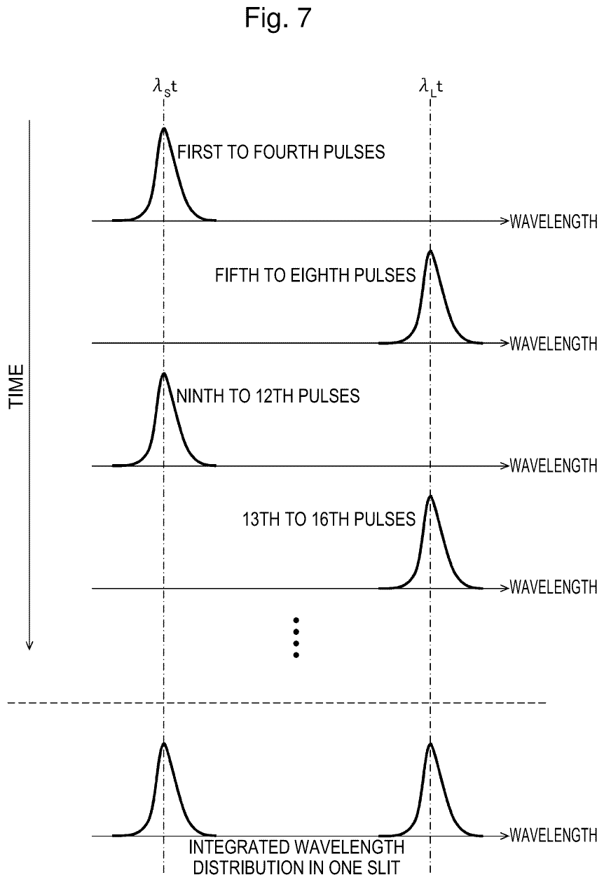

Without being limited to the wavelength change for each pulse illustrated in FIG. 6, for example, as illustrated in FIG. 7, the target short wavelength λ_{S}t and the target long wavelength λ_{L}t may be switched for every few pulses. FIG. 7 illustrates an example of switching the target short wavelength λ_{S}t and the target long wavelength λ_{L}t for every four pulses.

Moreover, without being limited to the examples illustrated in FIGS. 6 and 7, for example, a ratio of the number of pulses to be oscillated may be changed between the target wavelengths λ_{S}t and λ_{L}t to have a difference in integrated energy of the target short wavelength λ_{S}t and the target long wavelength λ_{L}t.

### 4.1.2.1 Example 1 of Wavelength Control Method

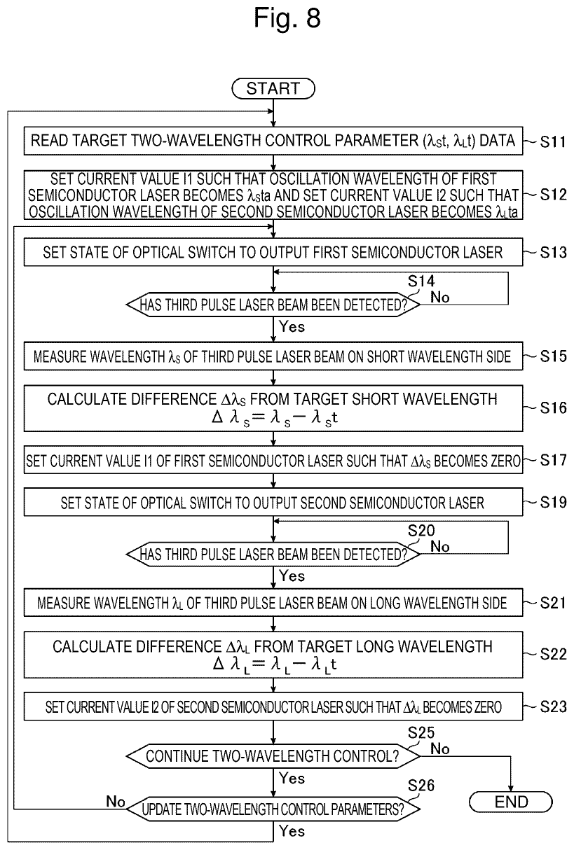

FIG. 8 is a flowchart illustrating Example 1 of a processing procedure of the laser control processor 12A in Embodiment 1. FIG. 8 illustrates an example of a case of changing the wavelength for each pulse as illustrated in FIG. 6.

In step S11, the laser control processor 12A reads target two-wavelength control parameter data from the exposure control processor 310. The target two-wavelength control parameter data includes data of the target short wavelength λ_{S}t and the target long wavelength λ_{L}t. The target short wavelength λ_{S}t and the target long wavelength λ_{L}t are examples of a “first target wavelength” and a “second target wavelength” in the present disclosure.

In step S12, the laser control processor 12A sets a current value I1 such that the wavelength of the first semiconductor laser 103 becomes λ_{S}ta. In addition, the laser control processor 12A sets a current value I2 such that the wavelength of the second semiconductor laser 104 becomes λ_{L}ta.

The wavelength λ_{S}ta of the first semiconductor laser 103 becomes the target short wavelength λ_{S}t after wavelength conversion by the wavelength conversion system 108, and is equivalent to the target wavelength of the first semiconductor laser 103 corresponding to the target short wavelength λ_{S}t after the wavelength conversion. Similarly, the wavelength λ_{L}ta of the second semiconductor laser 104 becomes the target long wavelength λ_{L}t after the wavelength conversion by the wavelength conversion system 108, and is equivalent to the target wavelength of the second semiconductor laser 104 corresponding to the target long wavelength λ_{L}t after the wavelength conversion.

In step S13, the laser control processor 12A sets a state of the optical switch 105 to output the first seed laser beam of the first semiconductor laser 103.

In step S14, the laser control processor 12A determines whether or not the third pulse laser beam PL3 has been detected by the spectrum detector 40. If the third pulse laser beam PL3 has not been detected (step S14: No), the laser control processor 12A stands by until the third pulse laser beam PL3 is detected. If the third pulse laser beam PL3 has been detected (step S14: Yes), the laser control processor 12A advances processing to step S15.

In step S15, the laser control processor 12A measures the wavelength λ_{S} of the third pulse laser beam PL3 on the short wavelength side. The wavelength λ_{S} measured using the spectrum detector 40 is an example of a “measured value” in the present disclosure.

In step S16, the laser control processor 12A calculates a difference Δλ_{S} between the wavelength λ_{S} measured in step S15 and the target short wavelength λ_{S}t. That is, the laser control processor 12A calculates Δλ_{S}=λ_{S}−λ_{S}t.

In step S17, the laser control processor 12A sets the current value I1 of the first semiconductor laser 103 such that the difference Δλ_{S} calculated in step S16 becomes zero.

Steps S13 to S17 are processing steps of performing wavelength measurement and control at the time of a short wavelength.

Next, in step S19, the laser control processor 12A sets the state of the optical switch 105 to output the second seed laser beam of the second semiconductor laser 104.

In step S20, the laser control processor 12A determines whether or not the third pulse laser beam PL3 has been detected by the spectrum detector 40. If the third pulse laser beam PL3 has not been detected (step S20: No), the laser control processor 12A stands by until the third pulse laser beam PL3 is detected. If the third pulse laser beam PL3 has been detected (step S20: Yes), the laser control processor 12A advances the processing to step S21.

In step S21, the laser control processor 12A measures the wavelength λ_{L} of the third pulse laser beam PL3 on the long wavelength side. The wavelength λ_{L} measured using the spectrum detector 40 is an example of the “measured value” in the present disclosure.

In step S22, the laser control processor 12A calculates a difference Δλ_{L} between the wavelength λ_{L} measured in step S21 and the target long wavelength λ_{L}t. That is, the laser control processor 12A calculates Δλ_{L} (=λ_{L}−λ_{L}t).

In step S23, the laser control processor 12A sets the current value I2 of the second semiconductor laser 104 such that the difference Δλ_{L} calculated in step S22 becomes zero.

Steps S19 to S23 are processing steps of performing the wavelength measurement and the control at the time of a long wavelength.

Next, in step S25, the laser control processor 12A determines whether or not to continue two-wavelength control. If continuing the two-wavelength control (step S25: Yes), the laser control processor 12A advances the processing to step S24. If not continuing the two-wavelength control (step S25: No), the laser control processor 12A ends the processing of the flowchart illustrated in FIG. 8.

In step S26, the laser control processor 12A determines whether or not to update two-wavelength control parameters. If not updating the two-wavelength control parameters (step S26: No), the laser control processor 12A returns the processing to step S13. If updating the two-wavelength control parameters (step S26: Yes), the laser control processor 12A returns the processing to step S11.

### 4.1.2.2 Example 2 of Wavelength Control Method

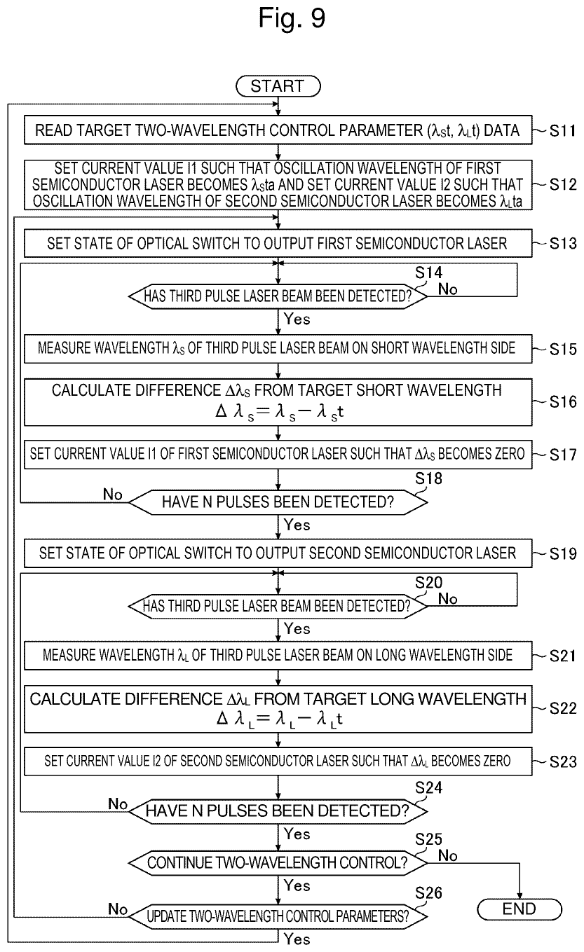

FIG. 9 is a flowchart illustrating Example 2 of the processing procedure of the laser control processor 12A in Embodiment 1. The flowchart illustrated in FIG. 9 is an example of a case of switching the wavelengths λ_{S} and λ_{L} for every N pulses, as described in FIG. 7. N is an integer equal to or larger than two. Description will be made on the difference of the flowchart illustrated in FIG. 9 from that in FIG. 8.

In the flowchart illustrated in FIG. 9, in step S11, the laser control processor 12A reads not only the two-wavelength parameter data but also data of N. In addition, in the flowchart illustrated in FIG. 9, step S18 is added between steps S17 and S19, and step S24 is added between steps S23 and S25. The other steps may be similar to those in FIG. 8.

In step S18, the laser control processor 12A determines whether or not N pulses have been detected. If N pulses have not been detected (step S18: No), the laser control processor 12A returns the processing to step S14.

If N pulses have been detected (step S18: Yes), the laser control processor 12A advances the processing to step S19. Steps S13 to S18 are the processing steps of performing the wavelength measurement and the control at the time of the short wavelength.

Further, in step S24, the laser control processor 12A determines whether or not N pulses have been detected. If N pulses have not been detected (step S24: No), the laser control processor 12A returns the processing to step S20. If N pulses have been detected (step S24: Yes), the laser control processor 12A advances the processing to step S25. Steps S19 to S24 are the processing steps of performing the wavelength measurement and the control at the time of the long wavelength.

### 4.2 Example of Semiconductor Laser

### 4.2.1 Configuration

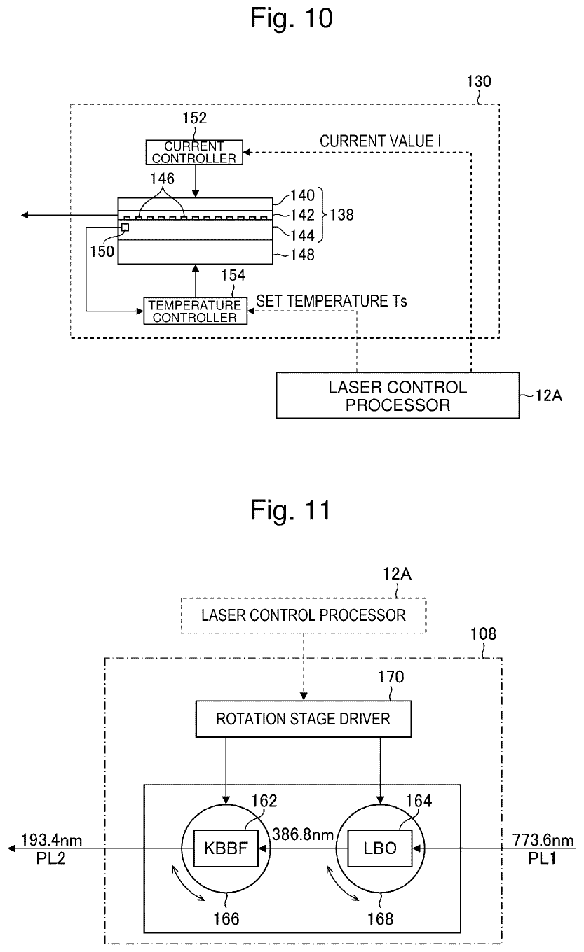

FIG. 10 is a diagram schematically illustrating a configuration of a semiconductor laser 130. The semiconductor laser 130 is a single longitudinal mode distributed feedback semiconductor laser, which can be applied to the first semiconductor laser 103 and the second semiconductor laser 104 in Embodiment 1.

The semiconductor laser 130 includes a semiconductor laser element 138, a Peltier element 148, a temperature sensor 150, a current controller 152, and a temperature controller 154. The semiconductor laser element 138 includes a first clad layer 140, an active layer 142, and a second clad layer 144, and includes a grating 146 at a boundary between the active layer 142 and the second clad layer 144.

### 4.2.2 Operation

An oscillation center wavelength of the semiconductor laser 130 can be changed by changing a set temperature Ts of the semiconductor laser element 138 and/or a current value I flowing through the semiconductor laser element 138. The laser control processor 12A sets the set temperature Ts and the current value I, and controls the temperature controller 154 and the current controller 152 respectively according to the set temperature Ts and the current value I.

When changing the oscillation wavelength of the semiconductor laser 130 at high speed, the current value I flowing through the semiconductor laser 130 is changed at high speed. Thus, the wavelength of the continuously oscillating laser beam can be changed at high speed.

### 4.2.3 Others

Each of the first semiconductor laser 103 and the second semiconductor laser 104 is not limited to the distributed feedback semiconductor laser, but may also be a distributed reflector (Distributed Bragg Reflector: DBR) semiconductor laser or a sampled grating distributed reflector (Sampled Grating Distributed Bragg Reflector:

SG-DBR) semiconductor laser, for example.

### 4.3 Example of Wavelength Conversion System

### 4.3.1 Configuration

FIG. 11 is a diagram schematically illustrating a configuration example of the wavelength conversion system 108. The wavelength conversion system 108 includes a KBBF crystal 162, an LBO crystal 164, a rotation stage 166, a rotation stage 168, and a rotation stage driver 170. Each of the KBBF crystal 162 and the LBO crystal 164 is an example of a “first nonlinear crystal” in the present disclosure.

The KBBF crystal 162 is disposed on the rotation stage 166. The LBO crystal 164 is disposed on the rotation stage 168. In order to rotate the nonlinear crystal at high speed, each of the rotation stage 166 and the rotation stage 168 may be a rotation stage that includes a piezoelectric element. The rotation stage driver 170 controls angles of the rotation stage 166 and the rotation stage 168.

### 4.3.2 Operation

A first pulse laser beam PL1 input to the wavelength conversion system 108 is incident on the LBO crystal 164. The LBO crystal 164 converts the first pulse laser beam PL1 having the wavelength of about 773.6 nm to a pulse laser beam having the wavelength of about 386.8 nm, which is second harmonic light.

The KBBF crystal 162 converts the pulse laser beam having the wavelength of about 386.8 nm output from the LBO crystal 164 to a second pulse laser beam PL2 having the wavelength of about 193.4 nm, which is the second harmonic light.

The second pulse laser beam PL2 converted to the wavelength of about 193.4 nm is output from the wavelength conversion system 108.

In single wavelength oscillation, an incident angle of each nonlinear crystal is controlled such that wavelength conversion efficiency is maximized at the target wavelength λt (to achieve phase matching).

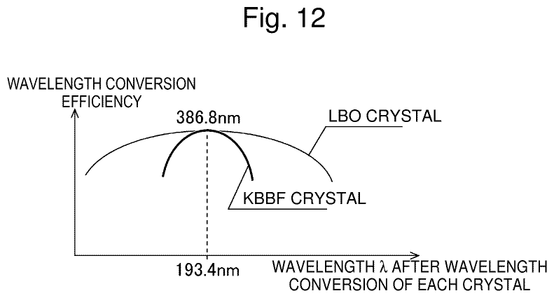

FIG. 12 is a graph illustrating wavelength conversion efficiency curves of the KBBF crystal 162 and the LBO crystal 164, respectively. For example, as illustrated in FIG. 12, the incident angle of each nonlinear crystal is controlled such that the wavelength conversion efficiency is maximized at the wavelength of 193.4 nm.

From FIG. 12, the wavelength conversion efficiency changes as the wavelength changes. Therefore, when a target wavelength difference Δλt of the two-wavelength spectrum to be described later is large, the wavelength conversion efficiency decreases and the pulse energy E drops unless the incident angles of the nonlinear crystals are controlled to maximize the wavelength conversion efficiency for each pulse.

Moreover, the change in wavelength conversion efficiency when the wavelength changes is significant for the KBBF crystal 162 illustrated on a downstream side of FIG. 11, while the change for the LBO crystal 164 is small. For this reason, until the target wavelength difference Δλt reaches a certain value, the incident angle control of only the KBBF crystal 162 can suppress decrease in pulse energy E.

### 4.3.3 Method for Controlling Incident Angle of Nonlinear Crystal

### 4.3.3.1 Flowchart Example

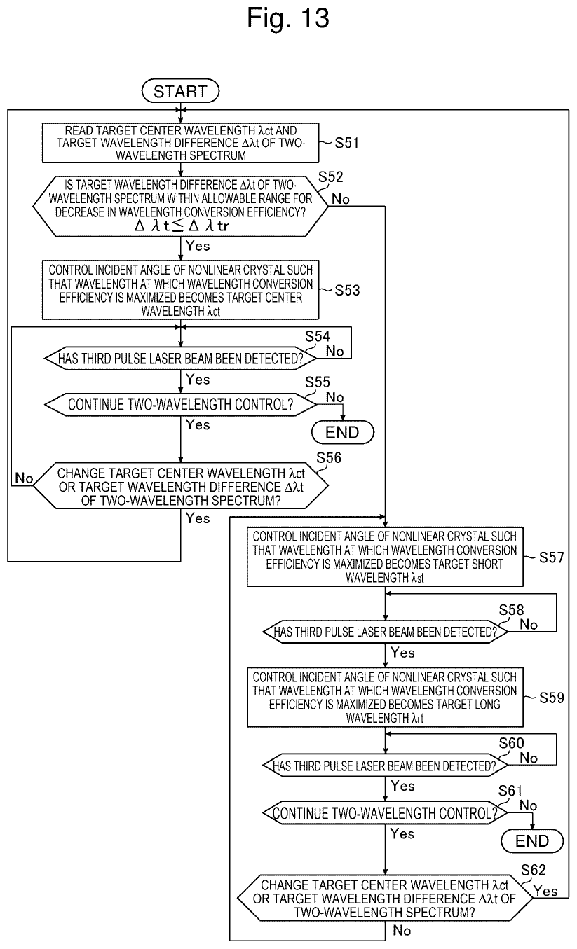

FIG. 13 is a flowchart illustrating an example of controlling the incident angle of the nonlinear crystal, executed by the laser control processor 12A.

In step S51, the laser control processor 12A reads a target center wavelength λct of the two-wavelength spectrum and a calculated value of the target wavelength difference Δλt from the two-wavelength control parameter data received from the exposure control processor 310. The target center wavelength λct is an average value of the target short wavelength λ_{S}t and the target long wavelength λ_{L}t, that is, (λ_{S}t+λ_{L}t)/2. The target wavelength difference Δλt is a difference between the target long wavelength λ_{L}t and the target short wavelength λ_{S}t, that is, λ_{L}t−λ_{S}t.

In step S52, the laser control processor 12A determines whether or not the target wavelength difference Δλt of the two-wavelength spectrum is within an allowable range Δλtr for the decrease in wavelength conversion efficiency. That is, the laser control processor 12A determines whether or not Δλt≤Δλtr is satisfied. The allowable range Δλtr may be, for example, a range of 1 pm to 2 pm. If Δλt≤Δλtr is satisfied (step S52: Yes), the laser control processor 12A advances the processing to step S53. If Δλt≤Δλtr is not satisfied (step S52: No), the laser control processor 12A advances the processing to step S57.

In step S53, the laser control processor 12A controls the incident angle of the nonlinear crystal such that the wavelength at which the wavelength conversion efficiency is maximized becomes the target center wavelength λct.

In step S54, the laser control processor 12A determines whether or not the third pulse laser beam PL3 has been detected by the spectrum detector 40. If the third pulse laser beam PL3 has not been detected (step S54: No), the laser control processor 12A stands by until the third pulse laser beam PL3 is detected. If the third pulse laser beam PL3 has been detected (step S54: Yes), the laser control processor 12A advances the processing to step S55.

In step S55, the laser control processor 12A determines whether or not to continue the two-wavelength control. If continuing the two-wavelength control (step S55: Yes), the laser control processor 12A advances the processing to step S56.

If not continuing the two-wavelength control (step S55: No), the laser control processor 12A ends the processing of the flowchart in FIG. 13.

In step S56, the laser control processor 12A determines whether or not to change the target center wavelength λct or the target wavelength difference Δλt of the two-wavelength spectrum. If not changing the target center wavelength λct or the target wavelength difference Δλt of the two-wavelength spectrum (step S56: No), the laser control processor 12A returns the processing to step S54. If changing the target center wavelength λct or the target wavelength difference Δλt of the two-wavelength spectrum (step S56: Yes), the laser control processor 12A returns the processing to step S51.

In step S57, the laser control processor 12A controls the incident angle of the nonlinear crystal such that the wavelength at which the wavelength conversion efficiency is maximized becomes the target short wavelength λ_{S}t.

In step S58, the laser control processor 12A determines whether or not the third pulse laser beam PL3 has been detected by the spectrum detector 40. If the third pulse laser beam PL3 has not been detected (step S58: No), the laser control processor 12A stands by until the third pulse laser beam PL3 is detected. If the third pulse laser beam PL3 has been detected (step S58: Yes), the laser control processor 12A advances the processing to step S59.

In step S59, the laser control processor 12A controls the incident angle of the nonlinear crystal such that the wavelength at which the wavelength conversion efficiency is maximized becomes the target long wavelength λ_{L}t

In step S60, the laser control processor 12A determines whether or not the third pulse laser beam PL3 has been detected. If the third pulse laser beam PL3 has not been detected (step S60: No), the laser control processor 12A stands by until the third pulse laser beam PL3 is detected. If the third pulse laser beam PL3 has been detected (step S60: Yes), the laser control processor 12A advances the processing to step S61.

In step S61, the laser control processor 12A determines whether or not to continue the two-wavelength control. If not continuing the two-wavelength control (step S61: No), the laser control processor 12A ends the processing of the flowchart illustrated in FIG. 13. If continuing the two-wavelength control (step S61: Yes), the laser control processor 12A advances the processing to step S62.

In step S62, the laser control processor 12A determines whether or not to change the target center wavelength λct or the target wavelength difference Δλt of the two-wavelength spectrum. If changing the target center wavelength λct or the target wavelength difference Δλt of the two-wavelength spectrum (step S62: Yes), the laser control processor 12A returns the processing to step S51. If not changing the target center wavelength Act or the target wavelength difference Δλt of the two-wavelength spectrum (step S62: No), the laser control processor 12A returns the processing to step S57.

Note that, while FIG. 13 illustrates the control in the case of changing the wavelength for each pulse as described in FIG. 6, the control of the incident angle in the case of changing the wavelength for every N pulses as described in FIG. 7 is basically same as the flowchart illustrated in FIG. 13. In the case of changing the wavelength for every N pulses, it is determined whether or not N pulses have been detected in each of steps S58 and S60.

### 4.3.3.2 Operation

As illustrated in FIG. 13, the laser control processor 12A determines whether or not the target wavelength difference Δλt of the two-wavelength spectrum is within the allowable range Δλtr for the decrease in wavelength conversion efficiency (step S52). Based on this determination result, the laser control processor 12A switches the control of the incident angle of the nonlinear crystal.

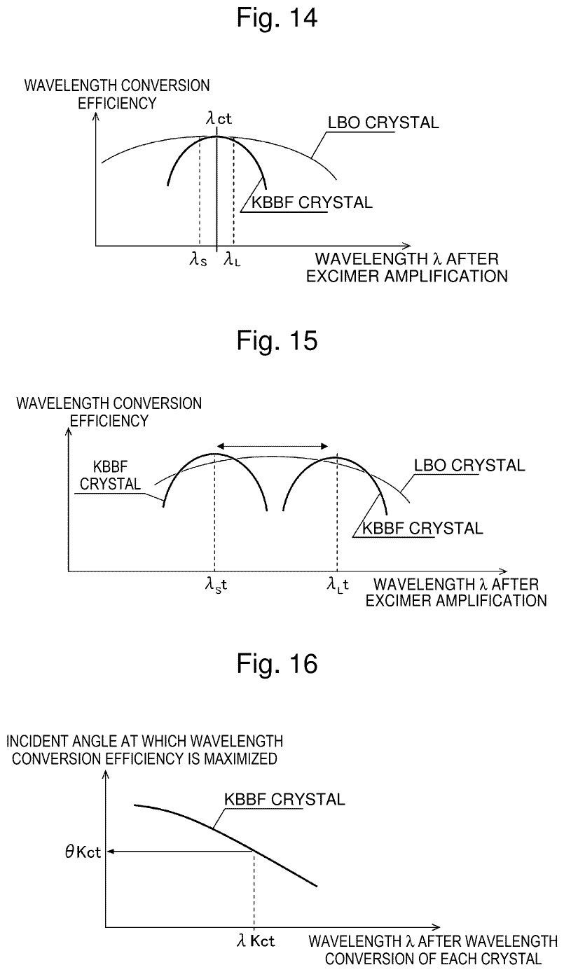

FIGS. 14 and 15 are graphs representing the relation between the wavelength λ after excimer amplification and the wavelength conversion efficiency. In FIGS. 14 and 15, a horizontal axis represents the wavelength λ after the excimer amplification, and a vertical axis represents the wavelength conversion efficiency.

When the target wavelength difference Δλt of the two-wavelength spectrum is within the allowable range λtr for the decrease in wavelength conversion efficiency, as illustrated in FIG. 14, the laser control processor 12A controls the incident angle of the nonlinear crystal to achieve the maximum wavelength conversion efficiency at the target center wavelength λct of the two-wavelength spectrum (Step S53).

For example, when the wavelength λ after the wavelength conversion of the KBBF crystal 162 and the incident angle at which the wavelength conversion efficiency is maximized are in the relation illustrated in FIG. 16 and the target center wavelength after the wavelength conversion is λKct, the laser control processor 12A controls the incident angle of the KBBF crystal 162 to θKct. For the relation illustrated in FIG. 16, an approximate curve may be obtained and stored in a storage unit of the laser control processor 12A, or the relation may be stored as table data in the storage unit of the laser control processor 12A. Note that the storage unit may be a combination of a memory as a main storage device and a storage as an auxiliary storage device. The laser control processor 12A retrieves information regarding the incident angle θkct at which the wavelength conversion efficiency is maximized corresponding to the target center wavelength λKct from the approximate curve or the table data stored in the storage unit. Further, in addition to controlling the incident angle of the KBBF crystal 162, the laser control processor 12A may also control the incident angle to maximize the wavelength conversion efficiency of the LBO crystal 164.

On the other hand, when the target wavelength difference Δλt of the two-wavelength spectrum is not within the allowable range Δλtr for the decrease in wavelength conversion efficiency, as illustrated in FIG. 15, the laser control processor 12A changes the incident angle of the nonlinear crystal for each pulse to achieve the maximum wavelength conversion efficiency at each of the target short wavelength λ_{S}t and the target long wavelength λ_{L}t (step S57, step S59).

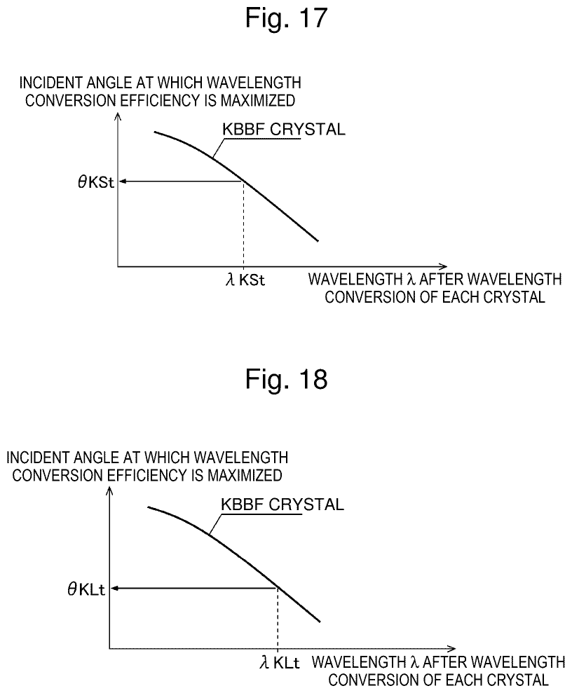

At the time of the target short wavelength λ_{S}t, for example, based on the relation between the wavelength λ after the wavelength conversion of the KBBF crystal 162 and the incident angle at which the wavelength conversion efficiency is maximized, the laser control processor 12A controls the incident angle of the KBBF crystal 162 to θKSt when the target short wavelength after the wavelength conversion is λKSt, as illustrated in FIG. 17. The relation illustrated in FIG. 17 is the same as the relation illustrated in FIG. 16, and information stored in the storage unit of the laser control processor 12A as an approximate curve or table data is applied. The relation illustrated in FIG. 18, which is to be described later, is also the same. Further, in addition to controlling the incident angle of the KBBF crystal 162, the laser control processor 12A may also control the incident angle to maximize the wavelength conversion efficiency of the LBO crystal 164.

Similarly, at the time of the target long wavelength λ_{L}t, for example, based on the relation between the wavelength λ after the wavelength conversion of the KBBF crystal 162 and the incident angle at which the wavelength conversion efficiency is maximized, the laser control processor 12A controls the incident angle of the KBBF crystal 162 to θKLt when the target short wavelength after the wavelength conversion is λKLt, as illustrated in FIG. 18. Further, in addition to controlling the incident angle of the KBBF crystal 162, the laser control processor 12A may also control the incident angle to maximize the wavelength conversion efficiency of the LBO crystal 164.

### 4.4 Effect

With the laser apparatus 100 according to Embodiment 1, even at a repetition frequency of 4 kHz or higher, the wavelength of the third pulse laser beam PL3 to be output can be stabilized at the target two wavelengths (λ_{S}t and λ_{L}t).

Moreover, even when the two-wavelength control parameters are changed, the wavelength of the third pulse laser beam PL3 to be output can be stabilized at the target two wavelengths (λ_{S}t and λ_{L}t).

Further, according to the laser apparatus 100, since the change in wavelength conversion efficiency in the wavelength conversion system 108 associated with the two-wavelength control is suppressed, the pulse energy E of the third pulse laser beam PL3 to be output can be stabilized at the target pulse energy Et.

### 5. Embodiment 2

### 5.1 Configuration

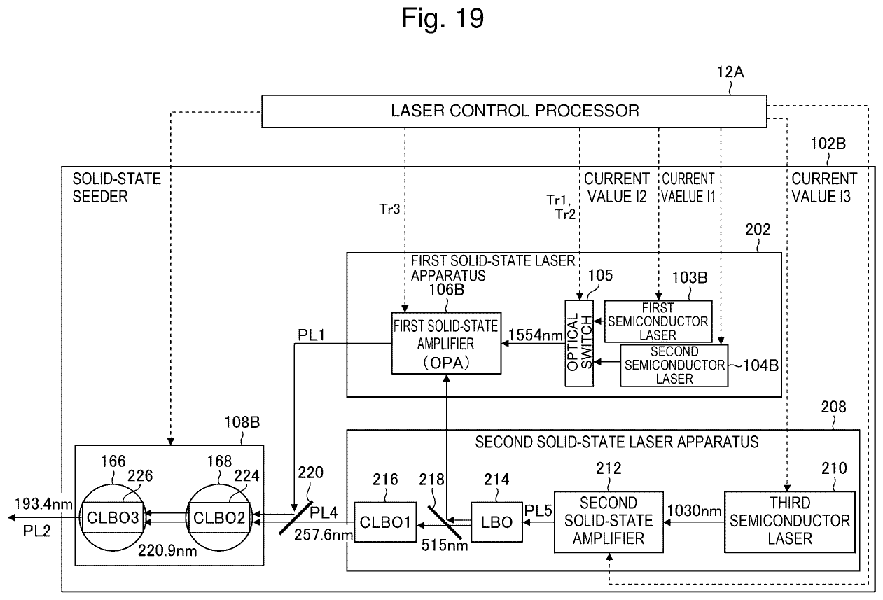

FIG. 19 is a diagram schematically illustrating a configuration of a solid-state seeder 102B applied to the laser apparatus 100 according to Embodiment 2. Instead of the solid-state seeder 102 illustrated in the laser apparatus 100 illustrated in FIG. 5, the solid-state seeder 102B illustrated in FIG. 19 may be employed.

The solid-state seeder 102B includes a first solid-state laser apparatus 202, a second solid-state laser apparatus 208, a dichroic mirror 220, and a wavelength conversion system 108B.

The first solid-state laser apparatus 202 includes a first semiconductor laser 103B, a second semiconductor laser 104B, the optical switch 105, and a first solid-state amplifier 106B.

Each of the first semiconductor laser 103B and the second semiconductor laser 104B continuously oscillates in the single longitudinal mode around a wavelength of 1554 nm, and both have slightly different wavelengths. Each of the first semiconductor laser 103B and the second semiconductor laser 104B may be a continuously oscillating distributed feedback semiconductor laser. The wavelengths of the first semiconductor laser 103B and the second semiconductor laser 104B are within a range of 1480 nm to 1580 nm respectively, and the wavelength difference between the two may be within a range of 1 pm to 110 pm.

The first solid-state amplifier 106B pulses the laser beam selected by the optical switch 105 and amplifies the energy of the laser beam.

The first solid-state amplifier 106B is an optical parametric amplifier (OPA). The OPA may be, for example, PPLN (periodically poled lithium niobate: periodically poled lithium niobate crystal) or PPKTP (periodically poled KTP: periodically poled titanyl potassium phosphate crystal).

The OPA uses the pulse laser beam having the wavelength of 1030 nm, which is to be described later, as pump light, and pulse-amplifies the selected seed laser beam output from the optical switch 105.

The second solid-state laser apparatus 208 includes a third semiconductor laser 210, a second solid-state amplifier 212, a plurality of nonlinear crystals (an LBO crystal 214 and a first CLBO crystal 216) that convert the wavelength to fourth harmonic light, and a dichroic mirror 218. The LBO crystal 214 and the first CLBO crystal 216 are examples of a “second nonlinear crystal” in the present disclosure. “CLBO” is represented by a chemical formula of CsLiB₆O₁₀.

The third semiconductor laser 210 continuously oscillates in the single longitudinal mode around 1030 nm. The third semiconductor laser 210 may be a continuously oscillating distributed feedback semiconductor laser.

The second solid-state amplifier 212 pulses the laser beam output from the third semiconductor laser 210 and amplifies the energy of the laser beam.

The LBO crystal 214 converts a fifth pulse laser beam PL5 having the wavelength of 1030 nm output from the second solid-state amplifier 212 to the second harmonic light having the wavelength of 515 nm.

The dichroic mirror 218 is disposed on an optical path between the LBO crystal 214 and the first CLBO crystal 216, highly transmits the pulse laser beam having the wavelength of 515 nm, and highly reflects the pulse laser beam having the wavelength of 1030 nm. The dichroic mirror 218 is disposed such that the highly reflected pulse laser beam having the wavelength of 1030 nm enters the solid-state amplifier 106B as the pump light.

The wavelength conversion system 108B includes a second CLBO crystal 224, a third CLBO crystal 226, and the rotation stages 168 and 166 that change the incident angles, respectively. In FIG. 19, the first CLBO crystal 216, the second CLBO crystal 224, and the third CLBO crystal 226 are denoted as “CLBO1”, “CLBO2”, and “CLBO3”, respectively.

The second CLBO crystal 224 is disposed on the rotation stage 168, and the third CLBO crystal 226 is disposed on the rotation stage 166.

The dichroic mirror 220 highly reflects the first pulse laser beam PL1 having the wavelength of about 1554 nm output from the first solid-state laser apparatus 202, highly transmits a fourth pulse laser beam PL4 having the wavelength of 257.6 nm output from the second solid-state laser apparatus 208, and is disposed such that both pulse laser beams coaxially enter the wavelength conversion system 108B.

Other configurations may be similar to those of the laser apparatus 100 according to Embodiment 1.

### 5.2 Operation

In the solid-state seeder 102B, by fixing the wavelength of the fourth pulse laser beam PL4 output from the second solid-state laser apparatus 208 and changing the wavelength of the first pulse laser beam PL1 output from the first solid-state laser apparatus 202 for each pulse, the wavelength of the second pulse laser beam PL2 output from the wavelength conversion system 108B is changed.

The laser control processor 12A in Embodiment 2 causes the first semiconductor laser 103B and the second semiconductor laser 104B to continuously oscillate at all times. In addition, the laser control processor 12A fixes a current value I3 of the third semiconductor laser 210, causes the third semiconductor laser 210 to continuously oscillate, and causes a third seed laser beam, which is a CW laser beam having the wavelength of 1030 nm, to be output from the third semiconductor laser 210. The wavelength of 1030 nm is an example of a “third wavelength” in the present disclosure.

The second solid-state amplifier 212 pulses and amplifies the third seed laser beam output from the third semiconductor laser 210, and outputs the fifth pulse laser beam PL5.

As described above, the LBO crystal 214 converts the fifth pulse laser beam PL5 having the wavelength of 1030 nm output from the second solid-state amplifier 212 to the second harmonic light having the wavelength of 515 nm.

The dichroic mirror 218 highly transmits the pulse laser beam having the wavelength of 515 nm. The first CLBO crystal 216 converts the pulse laser beam having the wavelength of 515 nm to the second harmonic light having the wavelength of 257.6 nm. Further, the dichroic mirror 218 highly reflects the fifth pulse laser beam PL5 having the wavelength of 1030 nm, which has not been wavelength-converted in the LBO crystal 214, to make it enter the first solid-state amplifier 106B of the first solid-state laser apparatus 202 as the pump light.

The first pulse laser beam PL1 having the wavelength of about 1554 nm output from the first solid-state laser apparatus 202 and the fourth pulse laser beam PL4 having the wavelength of 257.6 nm output from the first CLBO crystal 216 are subjected to a sum frequency generation by the second CLBO crystal 224, and are wavelength-converted to the wavelength of about 220.9 nm. Further, by the third CLBO crystal 226, the pulse laser beam having the wavelength of about 220.9 nm and the first pulse laser beam PL1 having the wavelength of about 1554 nm are subjected to the sum frequency generation, and are wavelength-converted to the wavelength of about 193.4 nm.

The laser control processor 12A can alternately change the wavelength of the second pulse laser beam PL2 by alternately switching the laser beam to be transmitted to the subsequent stage by the optical switch 105.

For example, by setting the wavelength of the laser beam output from the first semiconductor laser 103B to 1552.800 nm and the wavelength of the laser beam output from the second semiconductor laser 104B to 1552.840 nm, the wavelength of the second pulse laser beam PL2 output from the solid-state seeder 102B can be set to the two wavelengths of 193.400 nm and 193.401 nm.

A control flow for the wavelength change executed by the laser control processor 12A in Embodiment 2 may be similar to that in FIG. 8 or FIG. 9.

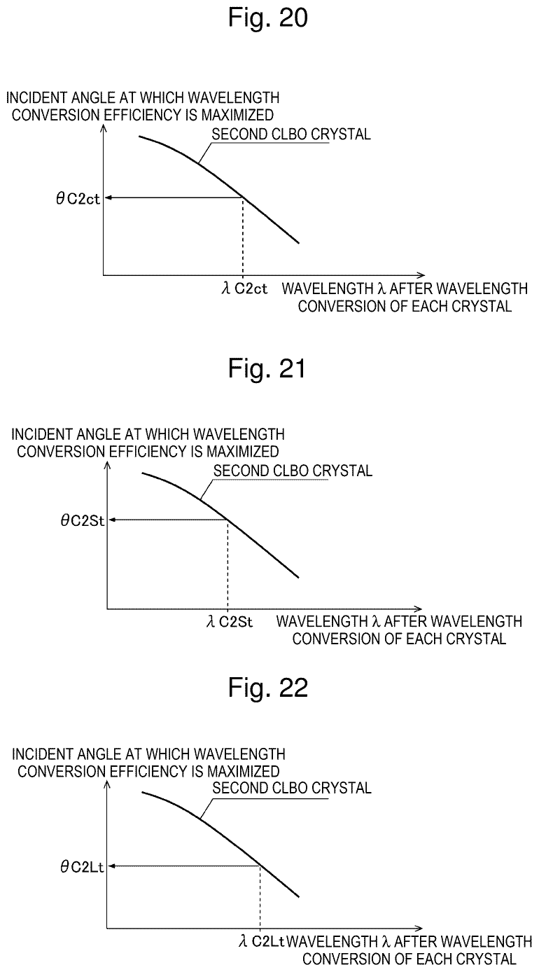

In addition, the control flow for the incident angle of the nonlinear crystal in the wavelength conversion system 108 in Embodiment 2 may also be similar to that in FIG. 13. In step S53 of FIG. 13, for example, when the wavelength λ after the wavelength conversion of the second CLBO crystal 224 and the incident angle at which the wavelength conversion efficiency of the nonlinear crystal is maximized are in the relation illustrated in FIG. 20 and the target center wavelength after the wavelength conversion is λC2ct, the laser control processor 12A in Embodiment 2 controls the incident angle of the second CLBO crystal 224 to θC2ct. For the relation illustrated in FIG. 20, an approximate curve may be obtained and stored in the storage unit of the laser control processor 12A, or the relation may be stored as table data in the storage unit of the laser control processor 12A. Further, in addition to controlling the incident angle of the second CLBO crystal 224, the laser control processor 12A may also control the incident angle to maximize the wavelength conversion efficiency of the third CLBO crystal 226.

In step S57, for example, based on the relation between the wavelength λ after the wavelength conversion of the second CLBO crystal 224 and the incident angle at which the wavelength conversion efficiency of the nonlinear crystal is maximized, as illustrated in FIG. 21, when the target short wavelength after the wavelength conversion is λC2St, the laser control processor 12A controls the incident angle of the second CLBO crystal 224 to θC2St. The relation illustrated in FIG. 21 is the same as the relation illustrated in FIG. 20, and information stored in the storage unit of the laser control processor 12A as an approximate curve or table data is applied. The relation illustrated in FIG. 22, which is to be described later, is also the same. Further, in addition to controlling the incident angle of the second CLBO crystal 224, the laser control processor 12A may also control the incident angle to maximize the wavelength conversion efficiency of the third CLBO crystal 226.

In step S59, for example, based on the relation between the wavelength λ after the wavelength conversion of the second CLBO crystal 224 and the incident angle at which the wavelength conversion efficiency of the nonlinear crystal is maximized, as illustrated in FIG. 22, when the target long wavelength after the wavelength conversion is λC2Lt, the laser control processor 12A controls the incident angle of the second CLBO crystal 224 to θC2Lt. Further, in addition to controlling the incident angle of the second CLBO crystal 224, the laser control processor 12A may also control the incident angle to maximize the wavelength conversion efficiency of the third CLBO crystal 226.

### 5.3 Effect

According to Embodiment 2, the same effects as those of Embodiment 1 can be obtained.

### 6. Electronic Device Manufacturing Method

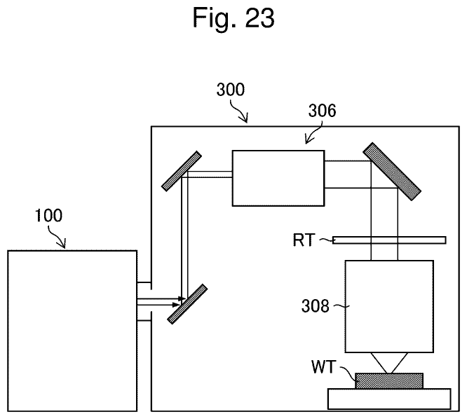

FIG. 23 is a diagram schematically illustrating a configuration of the exposure apparatus 300. In FIG. 23, the exposure apparatus 300 includes the illumination optical system 306 and the projection optical system 308. The laser beam generated by the laser apparatus 100 enters the exposure apparatus 300. The illumination optical system 306 illuminates a reticle pattern of the reticle stage RT with the laser beam that has entered from the laser apparatus 100. The laser beam having transmitted through the reticle is imaged on a non-illustrated workpiece disposed on a workpiece table WT by reduced projection through the projection optical system 308. The workpiece is a photosensitive substrate such as a semiconductor wafer on which photoresist is applied.

The exposure apparatus 300 translates the reticle stage RT and the workpiece table WT in directions opposite to each other in synchronization such that the workpiece is exposed to the laser beam reflecting the reticle pattern. A semiconductor device can be manufactured through a plurality of processes after a device pattern is transferred onto the semiconductor wafer through an exposure process as described above. The semiconductor device is an example of an “electronic device” in the present disclosure.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it is also obvious for those skilled in the art that embodiments of the present disclosure would be appropriately combined.

The terms used throughout the present specification and the appended claims should be interpreted as “non-limiting terms” unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser apparatus comprising:
a first semiconductor laser configured to output a continuously oscillating first seed laser beam having a first wavelength;
a second semiconductor laser configured to output a continuously oscillating second seed laser beam having a second wavelength different from the first wavelength;
an optical switch configured to output selected one of the first seed laser beam and the second seed laser beam as a selected seed laser beam;
a first solid-state amplifier configured to pulse and amplify the selected seed laser beam and to output a first pulse laser beam;
a wavelength conversion system configured to output a second pulse laser beam by wavelength conversion using the first pulse laser beam;
an excimer amplifier configured to amplify the second pulse laser beam and to output a third pulse laser beam;
a beam characteristic measuring instrument configured to measure a wavelength of the third pulse laser beam; and
a processor configured to select one of the first seed laser beam and the second seed laser beam as the selected seed laser beam based on a target wavelength, and to control a wavelength of the first semiconductor laser or the second semiconductor laser that outputs the selected seed laser beam based on the wavelength measured by the beam characteristic measuring instrument such that the wavelength of the third pulse laser beam becomes the target wavelength.

2. The laser apparatus according to claim 1, wherein
the processor
controls the wavelength of each of the first semiconductor laser and the second semiconductor laser by controlling at least one of a current value of a current flowing through a semiconductor of each of the first semiconductor laser and the second semiconductor laser and a temperature of the semiconductor.

3. The laser apparatus according to claim 1, wherein
a first target wavelength and a second target wavelength are set as the target wavelength.

4. The laser apparatus according to claim 3, wherein
the processor
controls the wavelength of the first semiconductor laser based on a measured value of the wavelength of the third pulse laser beam obtained when the first seed laser beam is selected as the selected seed laser beam such that the wavelength of the third pulse laser beam becomes the first target wavelength, and
controls the wavelength of the second semiconductor laser based on the measured value of the wavelength of the third pulse laser beam obtained when the second seed laser beam is selected as the selected seed laser beam such that the wavelength of the third pulse laser beam becomes the second target wavelength.

5. The laser apparatus according to claim 3, wherein
the wavelength conversion system includes
a first nonlinear crystal, and
a rotation stage configured to rotate the first nonlinear crystal, and
the processor
calculates a target center wavelength which is an average value of the first target wavelength and the second target wavelength, and
controls the rotation stage such that the wavelength at which wavelength conversion efficiency is maximized becomes the target center wavelength.

6. The laser apparatus according to claim 5, wherein
the processor
includes a storage unit configured to store a relation between the target center wavelength and an incident angle at which the wavelength conversion efficiency is maximized, and acquires information regarding the incident angle at which the wavelength conversion efficiency is maximized according to the target center wavelength from the relation stored in the storage unit.

7. The laser apparatus according to claim 1, wherein
the wavelength conversion system includes
a first nonlinear crystal, and
a rotation stage configured to rotate the first nonlinear crystal, and
the processor controls the rotation stage such that the wavelength at which wavelength conversion efficiency is maximized becomes the target wavelength.

8. The laser apparatus according to claim 1, wherein
the processor
includes a storage unit configured to store a relation between the target wavelength and an incident angle at which wavelength conversion efficiency is maximized, and acquires information regarding the incident angle at which the wavelength conversion efficiency is maximized according to the target wavelength from the storage unit.

9. The laser apparatus according to claim 1, wherein
each of the first wavelength and the second wavelength is in a range of 700 nm to 800 nm, and a difference between the first wavelength and the second wavelength is in a range of 1 pm to 110 pm.

10. The laser apparatus according to claim 1, further comprising
a solid-state laser apparatus configured to output a fourth pulse laser beam, wherein
the wavelength conversion system outputs the second pulse laser beam by wavelength conversion by a sum frequency generation using the first pulse laser beam and the fourth pulse laser beam.

11. The laser apparatus according to claim 10, wherein
the solid-state laser apparatus includes
a third semiconductor laser configured to output a continuously oscillating third seed laser beam having a third wavelength different from each of the first wavelength and the second wavelength,
a second solid-state amplifier configured to pulse and amplify the third seed laser beam and to output a fifth pulse laser beam, and
a second nonlinear crystal configured to subject the fifth pulse laser beam to wavelength conversion and to output fourth harmonic light which is the fourth pulse laser beam.

12. The laser apparatus according to claim 10, wherein
each of the first wavelength and the second wavelength is in a range of 1480 nm to 1580 nm, and a difference between the first wavelength and the second wavelength is in a range of 1 pm to 110 pm.

13. The laser apparatus according to claim 1, wherein
the processor
controls the wavelength of the first semiconductor laser or the second semiconductor laser such that a wavelength difference between the wavelength of the third pulse laser beam obtained when the first seed laser beam is selected as the selected seed laser beam and the wavelength of the third pulse laser beam obtained when the second seed laser beam is selected as the selected seed laser beam is within 1 pm.

14. The laser apparatus according to claim 1, wherein
the processor
causes the second pulse laser beam to be output by a repetition frequency of 4 kHz or more.

15. A laser apparatus wavelength control method comprising:
outputting a continuously oscillating first seed laser beam having a first wavelength by a first semiconductor laser;
outputting a continuously oscillating second seed laser beam having a second wavelength different from the first wavelength by a second semiconductor laser;
outputting selected one of the first seed laser beam and the second seed laser beam as a selected seed laser beam from an optical switch;
pulsing and amplifying the selected seed laser beam and outputting a first pulse laser beam by a first solid-state amplifier;
outputting a second pulse laser beam by wavelength conversion using the first pulse laser beam by a wavelength conversion system;
amplifying the second pulse laser beam and outputting a third pulse laser beam by an excimer amplifier;
measuring a wavelength of the third pulse laser beam by a beam characteristic measuring instrument; and
selecting one of the first seed laser beam and the second seed laser beam as the selected seed laser beam based on a target wavelength and controlling a wavelength of the first semiconductor laser or the second semiconductor laser that outputs the selected seed laser beam based on the wavelength measured by the beam characteristic measuring instrument such that the wavelength of the third pulse laser beam becomes the target wavelength.

16. An electronic device manufacturing method comprising:
generating a laser beam with a laser apparatus, the laser apparatus including
a first semiconductor laser configured to output a continuously oscillating first seed laser beam having a first wavelength,
a second semiconductor laser configured to output a continuously oscillating second seed laser beam having a second wavelength different from the first wavelength,
an optical switch configured to output selected one of the first seed laser beam and the second seed laser beam as a selected seed laser beam,
a first solid-state amplifier configured to pulse and amplify the selected seed laser beam and to output a first pulse laser beam,
a wavelength conversion system configured to output a second pulse laser beam by wavelength conversion using the first pulse laser beam,
an excimer amplifier configured to amplify the second pulse laser beam and to output a third pulse laser beam,
a beam characteristic measuring instrument configured to measure a wavelength of the third pulse laser beam, and
a processor configured to select one of the first seed laser beam and the second seed laser beam as the selected seed laser beam based on a target wavelength, and to control a wavelength of the first semiconductor laser or the second semiconductor laser that outputs the selected seed laser beam based on the wavelength measured by the beam characteristic measuring instrument such that the wavelength of the third pulse laser beam becomes the target wavelength;
outputting the laser beam to an exposure apparatus; and
exposing a photosensitive substrate to the laser beam in the exposure apparatus to manufacture an electronic device.
